(19) United States
(12) Patent Application Publication
(10) Pub. No.: US 2024/0026541 A1
(43) Pub. Date: Jan. 25, 2024

(54) INFORMATION PROCESSING APPARATUS, STORAGE MEDIUM, AND PROCESS CONDITION OPTIMIZATION METHOD

(71) Applicant: Tokyo Electron Limited, Tokyo (JP)

(72) Inventor: Shota YAMAZAKI, Yamanashi (JP)

(21) Appl. No.: 18/223,703

(22) Filed: Jul. 19, 2023

(30) Foreign Application Priority Data
Jul. 22, 2022 (JP) 2022-117385

(51) Int. Cl. C23C 16/52

(52) U.S. Cl. CPC C23C 16/52; H01L 21/67069

(57) ABSTRACT

An information processing apparatus includes: a registration reception unit that receives a registration of registration information for identifying log information of a desired process step from log information of a substrate processing apparatus that has performed a process including a plurality of steps according to a process condition; an identification unit that identifies the log information of the desired process step from the log information of the substrate processing apparatus, based on the registration information; a process condition acquisition unit that acquires a process condition of the desired process step from the identified log information of the desired process step; an optimization unit that optimizes the process condition of the desired process step, using the acquired process condition of the desired process step, and process result information of the process; and an output unit that outputs the optimized process condition of the desired process step.

### CROSS-REFERENCE TO RELATED APPLICATIONS

This application is based on and claims priority from Japanese Patent Application No. 2022-117385, filed on Jul. 22, 2022, with the Japan Patent Office, the disclosure of which is incorporated herein in its entirety by reference.

### TECHNICAL FIELD

The present disclosure relates to an information processing apparatus, a storage medium that stores a program, and a process condition optimization method.

### BACKGROUND

In a substrate processing apparatus that performs a process according to process conditions, a technology is used, which optimizes film formation conditions to implement a target film formation result. In the prior art, for example, the optimization of film formation conditions is performed in the manner that an operator or the like identifies log information of a film formation step from log information of the substrate processing apparatus that has performed the process according to the process conditions, and acquires the film formation conditions from the log information of the film formation step.

A technology is also known in the prior art, which performs an optimization calculation of a process recipe including process conditions such as a set pressure, a heater set temperature, and a gas flow rate of a substrate processing apparatus (see, e.g., Japanese Laid-Open Patent Publication No. 2008-091826).

Further, a technology is known in the prior art, which models a film formation process performed by a film forming apparatus through a machine learning, in order to investigate optimal film formation conditions to implement the target film formation result (see, e.g., Japanese Laid-Open Patent Publication No. 2022-028457).

### SUMMARY

According to an aspect of the present disclosure, an information processing apparatus includes: a registration reception unit that receives a registration of registration information for identifying log information of a desired process step from log information of a substrate processing apparatus that has performed a process including a plurality of steps according to a process condition; an identification unit that identifies the log information of the desired process step from the log information of the substrate processing apparatus, based on the registration information; a process condition acquisition unit that acquires a process condition of the desired process step from the log information of the desired process step identified by the identification unit; an optimization unit that optimizes the process condition of the desired process step, using the process condition of the desired process step acquired by the process condition acquisition unit, and process result information of the process; and an output unit that outputs the process condition of the desired process step optimized by the optimization unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram illustrating an example of a substrate processing system according to an embodiment.

FIG. 2 is a hardware configuration diagram illustrating an example of a computer.

FIG. 3 is a functional block diagram illustrating an example of an optimization device according to an embodiment.

FIG. 4 is a flow chart illustrating an example of a process, in which the substrate processing system optimizes process conditions of a substrate processing apparatus according to an embodiment.

FIG. 5 is a flow chart illustrating an example of a process condition optimization process.

FIG. 6 is a view illustrating an example of registration information according to an embodiment.

FIG. 7 is a view illustrating an example of log information of a substrate processing apparatus.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings.

<System Configuration>

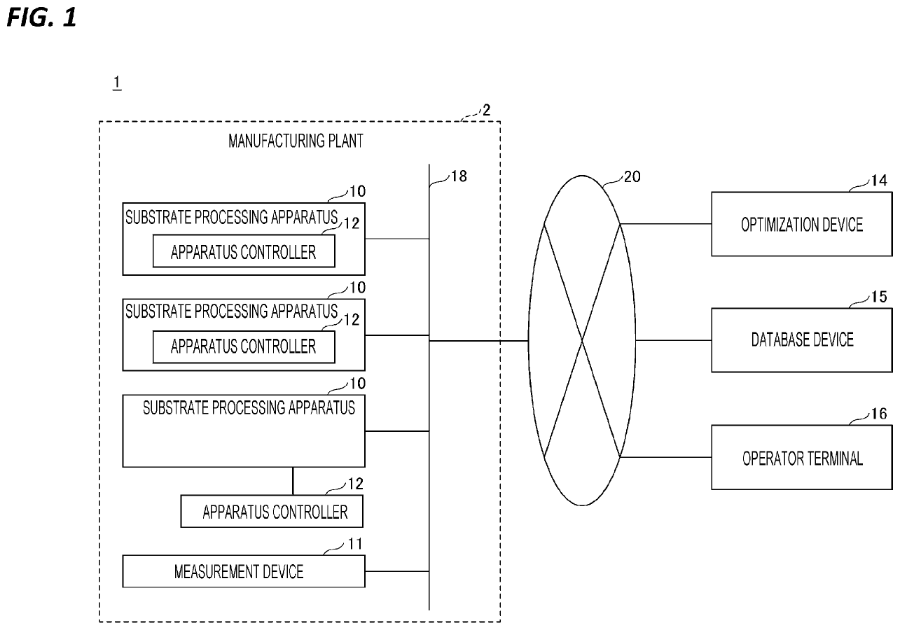

FIG. 1 is a configuration diagram illustrating a substrate processing system according to an embodiment. A substrate processing system 1 of FIG. 1 includes one or more substrate processing apparatuses 10, a measurement device 11, an apparatus controller 12, an optimization device 14, a database device 15, and an operator terminal 16. The one or more substrate processing apparatuses 10 and the apparatus controller 12 are installed in a manufacturing plant 2. The measurement device 11 is also installed in the manufacturing plant 2. The optimization device 14, the database device 15, and the operator terminal 16 may be installed in the manufacturing plant 2 or in another location other than the manufacturing plant 2. The substrate processing apparatus 10, the measurement device 11, the apparatus controller 12, the optimization device 14, the database device 15, and the operator terminal 16 are connected to each other for a communication via networks 18 and 20 such as the Internet and a local area network (LAN).

The substrate processing apparatus 10 performs a substrate processing such as a film formation, an etching, and an ashing, and is, for example, an apparatus for processing a semiconductor wafer or a glass substrate of a flat panel display. The substrate processing apparatus 10 is, for example, a semiconductor manufacturing apparatus, a heat treatment apparatus, or a film forming apparatus.

The substrate processing apparatus 10 receives a control command corresponding to process conditions such as a recipe or a macro from the apparatus controller 12, and performs a process including a plurality of steps according to the process conditions. The substrate processing apparatus 10 may be equipped with the apparatus controller 12 as illustrated in FIG. 1, or may not necessarily be equipped with the apparatus controller 12 as long as both are connected to each other for a communication. The apparatus controller 12 includes a computer that controls the substrate processing apparatus 10. The apparatus controller 12 outputs control commands to control the components of the substrate processing apparatus 10 according to the process conditions, thereby causing the substrate processing apparatus 10 to perform the process according to the process conditions. Further, the apparatus controller 12 has a man-machine interface function to receive an instruction for the substrate processing apparatus 10 from the operator and provide information on the substrate processing apparatus 10 to the operator.

As process result information of the process according to the process conditions, the measurement device 11 measures, for example, the film thickness or the refractive index of a semiconductor wafer after the process, and provides the process result information to the optimization device 14. The measurement device 11 may provide the process result information to the database device 15, to provide the process result information to the optimization device 14 via the database device 15.

The apparatus controller 12 provides, to the optimization device 14, log information that may identify the process conditions of the process performed by the substrate processing apparatus 10. The apparatus controller 12 may provide the log information to the database device 15, to provide the log information to the optimization device 14 via the database device 15.

The optimization device 14 optimizes the process conditions as described later, using the provided log information and process result information. The optimization device 14 outputs the optimized process conditions. For example, the optimization device 14 provides the optimized process conditions to the apparatus controller 12, to reflect the optimized process conditions in a process to be performed by the substrate processing apparatus 10. The optimization device 14 may display the optimized process conditions on the apparatus controller 12 or the operator terminal 16 to be confirmed by the operator, before reflecting the optimized process conditions in the process to be performed by the substrate processing apparatus 10. The configuration of the substrate processing system 1 of FIG. 1 is an example, and the optimization device 14 may be equipped in the substrate processing apparatus 10.

The database device 15 stores and manages various types of information necessary for processes that are executed by the substrate processing system 1 according to the present embodiment. For example, the database device 15 provides, to the optimization device 14, the log information of the substrate processing apparatus 10 that has performed the process according to the process conditions, and the process result information.

The operator terminal 16 is, for example, a personal computer (PC) or a smartphone operated by an operator such as an apparatus engineer or an analyst of the substrate processing apparatus 10 installed in the manufacturing plant 2.

The substrate processing system 1 of FIG. 1 is an example, and may be implemented with various examples of system configurations according to an application or a purpose. For example, the substrate processing system 1 may have various configurations, such as a configuration in which the apparatus controllers 12 of the plurality of respective substrate processing apparatuses 10 are integrated into an apparatus controller for the substrate processing apparatuses 10, or a configuration in which the apparatus controllers 12 are further divided.

<Hardware Configuration>

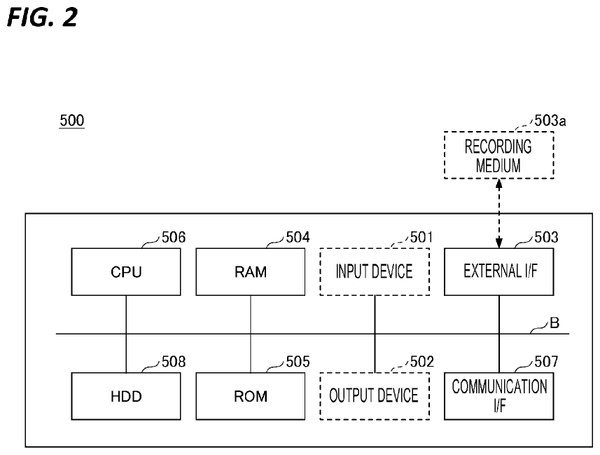

The apparatus controller 12, the optimization device 14, the database device 15, and the operator terminal 16 of the substrate processing system 1 of FIG. 1 are implemented by, for example, a computer having the hardware configuration illustrated in FIG. 2. FIG. 2 is a hardware configuration diagram illustrating an example of the computer.

A computer 500 of FIG. 2 includes, for example, an input device 501, an output device 502, an external interface 503, a random access memory (RAM) 504, a read only memory (ROM) 505, a central processing unit (CPU) 506, a communication OF 507, and a hard disk drive (HDD) 508, which are connected to each other by a bus B. The input device 501 and the output device 502 may be connected and used when necessary.

The input device 501 is, for example, a keyboard, a mouse, or a touch panel, and is used by a user to input each operation signal. The output device 502 is, for example, a display, and displays results of processes that are executed by the computer 500. The communication OF 507 is an interface that connects the computer 500 to the network 18 or 20. The HDD 508 is an example of a nonvolatile storage device that stores programs and data.

The external OF 503 is an interface with external devices. The computer 500 may execute read and/or write with respect to a recording media 503a such as a secure digital (SD) memory card via the external OF 503. The ROM 505 is an example of a nonvolatile semiconductor memory (storage device) that stores programs and data. The RAM 504 is an example of a volatile semiconductor memory (storage device) that temporarily stores programs and data.

The CPU 506 is an arithmetic device that reads programs or data from the storage device such as the ROM 505 or the HDD 508 onto the RAM 504, and executes processes, so as to control the entire computer 500 or implement the function thereof.

The apparatus controller 12, the optimization device 14, the database device 15, and the operator terminal 16 of FIG. 1 may implement various functions to be described later, by executing programs with the computer 500 having the hardware configuration illustrated in FIG. 2.

<Functional Configuration>

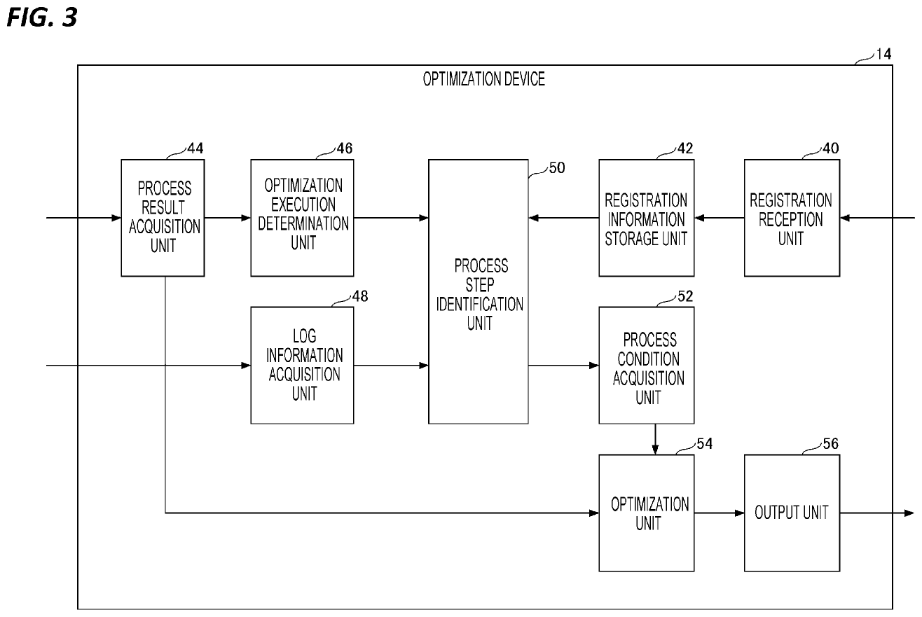

The optimization device 14 of the substrate processing system 1 according to the present embodiment is implemented by, for example, the functional blocks illustrated in FIG. 3. FIG. 3 is a functional block diagram illustrating an example of the optimization device according to the present embodiment. The functional block diagram of FIG. 3 omits the illustration of configuration unnecessary for the descriptions of the present embodiment.

The optimization device 14 of FIG. 3 executes programs for the optimization device 14, thereby implementing a registration reception unit 40, a registration information storage unit 42, a process result acquisition unit 44, an optimization execution determination unit 46, a log information acquisition unit 48, a process step identification unit 50, a process condition acquisition unit 52, an optimization unit 54, and an output unit 56.

The registration reception unit 40 receives a registration of registration information to be described later from, for example, the operator. The registration information refers to information for identifying log information of a desired process step from the log information of the substrate processing apparatus 10 that has performed the process including the plurality of steps. The desired process step is, for example, a film formation step or an etching step.

The registration information for identifying the log information of the desired process step is, for example, a process gas used in the desired process step. The registration information for identifying the log information of the desired process step may be, for example, information of a process gas used in the desired process step and a process type.

The registration information for identifying log information of a desired film formation step is, for example, a film formation gas used in the film formation step. The registration information for identifying log information of a desired etching step is, for example, an etching gas used in the etching step. The registration information storage unit 42 stores the registration information received by the registration reception unit 40.

As the process result information of the process according to the process conditions, the process result acquisition unit 44 acquires the measurement values such as the film thickness or the refractive index of the semiconductor wafer after the process. The process result acquisition unit 44 acquires the process result information from, for example, the measurement device 11 or the database device 15. The optimization execution determination unit 46 determines whether the process result satisfies a requirement, based on the process result information acquired by the process result acquisition unit 44. The requirement is registered by, for example, the operator.

When the process result does not satisfy the requirement, the optimization execution determination unit 46 instructs the process step identification unit 50 to execute the optimization of the process conditions. The log information acquisition unit 48 acquires the log information of the substrate processing apparatus 10 subjected to the optimization of the process conditions (log information to be optimized), from the apparatus controller 12 or the database device 15.

The process step identification unit 50 acquires the registration information such as the process gas or the etching gas stored in the registration information storage unit 42. Further, the process step identification unit 50 acquires the log information to be optimized from the log information acquisition unit 48. Based on the acquired registration information, the process step identification unit 50 identifies the log information of the desired process step such as the film formation step or the etching step, from the log information to be optimized. The process condition acquisition unit 52 acquires the process conditions of the desired process step such as film formation conditions or etching conditions, from the log information of the desired process step such as the film formation step or the etching step identified by the process step identification unit 50.

The optimization unit 54 performs an optimization calculation to optimize the process conditions of the desired process step, such as the film formation conditions or the etching conditions, by using the process conditions of the desired process step such as the film formation conditions or the etching conditions acquired by the process condition acquisition unit 52, and the process result information of the process according to the process conditions. The optimization calculation for optimizing the process conditions is performed by a known algorithm.

The output unit 56 outputs the process conditions of the desired process step that have been optimized by the optimization unit 54. The output unit 56 may provide the optimized process conditions to the apparatus controller 12, to reflect the optimized process conditions in the process to be executed by the substrate processing apparatus 10. The output unit 56 may display the optimized process conditions on the apparatus controller 12 or the operator terminal 16.

<Process>

In the present embodiment, a process condition optimization calculation is performed by identifying the log information of the desired process step from the log information of the substrate processing apparatus 10 that has performed the process including the plurality of steps according to the process conditions, and acquiring the process conditions of the desired process step from the identified log information.

In order to optimize the process conditions, it is necessary to acquire the unoptimized process conditions from the log information of the desired process step, and further acquire the process result information of the process according to the unoptimized process conditions. Thus, the optimization device 14 of the present embodiment has a structure to automatically identify the log information of the desired process step from the log information of the substrate processing apparatus 10.

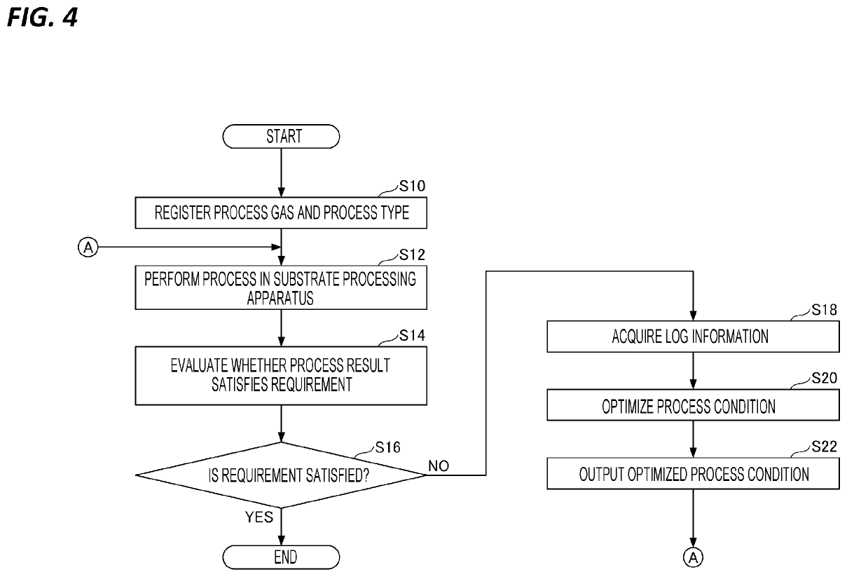

FIG. 4 is a flow chart illustrating an example of a process, in which the substrate processing system optimizes the process conditions of the substrate processing apparatus according to the present embodiment.

In step S10, the registration reception unit 40 of the optimization device 14 receives a registration of a process gas and a process type from, for example, the operator, as the registration information for identifying the log information of the desired process step from the log information of the substrate processing apparatus 10.

FIG. 6 is a view illustrating an example of the registration information according to the present embodiment. FIG. 6 represents registration information for registering log information of a film formation step of a film Z using gases A and B, and registration information for identifying log information of an etching step using gases M and N. The process type of FIG. 6 represents a process type such as the film formation or the etching. The process gas of FIG. 6 represents a gas type such as the film formation gas or the etching gas used in the desired process step among the steps included in the process. The step that uses the process gas registered in FIG. 6 is the desired process step.

In step S12, the substrate processing apparatus 10 performs the process including the plurality of steps according to the process conditions. In step S14, the process result acquisition unit 44 of the optimization device 14 acquires the measurement values such as the film thickness or the refractive index of the semiconductor wafer after the process, as the process result information.

The optimization execution determination unit 46 of the optimization device 14 evaluates whether the process result satisfies the requirement, based on the process result information. When it is determined that the requirement is satisfied, the optimization execution determination unit 46 terminates the process of the flow chart of FIG. 4. When it is determined that the requirement is not satisfied, the optimization execution determination unit 46 instructs the process step identification unit 50 to perform the optimization of the process conditions.

In step S18, the log information acquisition unit 48 of the optimization device 14 acquires the log information of the substrate processing apparatus 10 subjected to the optimization of the process conditions.

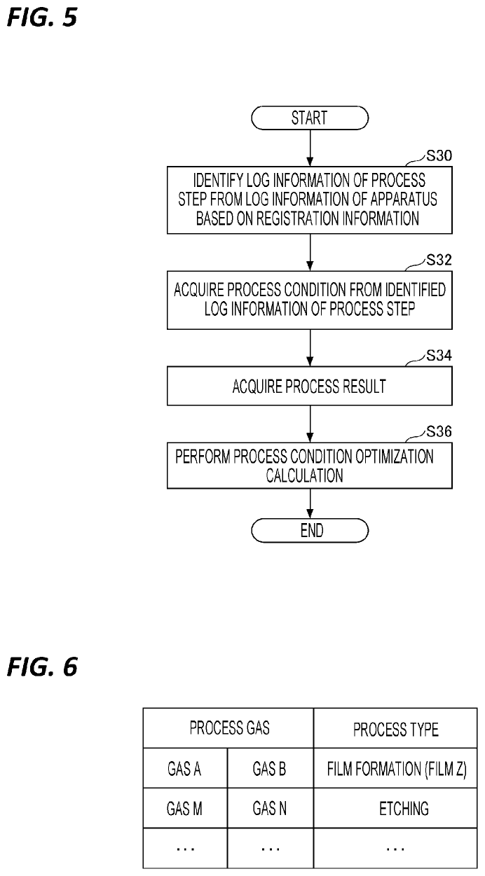

In step S20, the optimization device 14 performs the process condition optimization process illustrated in FIG. 5. FIG. 5 is a flow chart illustrating an example of the process condition optimization process.

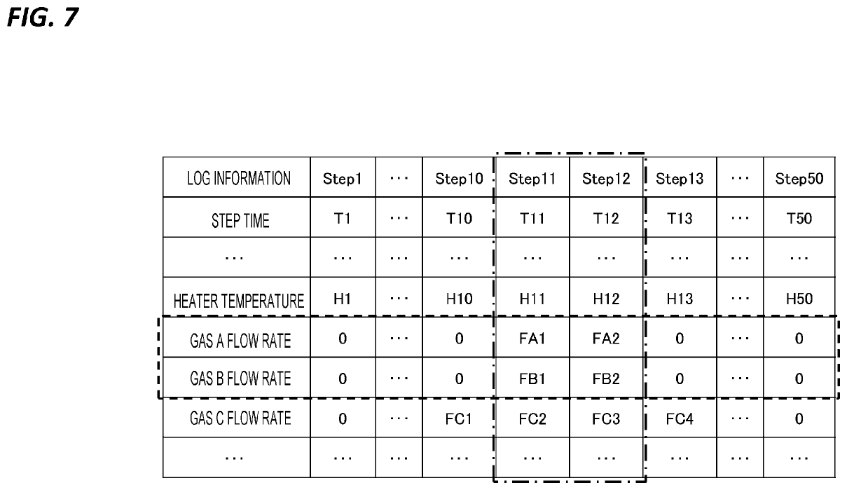

In step S30, the process step identification unit 50 of the optimization device 14 acquires, for example, the registration information of FIG. 6 stored in the registration information storage unit 42. Further, the process step identification unit 50 acquires the log information of the substrate processing apparatus 10 subjected to the optimization of the process conditions, as illustrated in, for example, FIG. 7, from the log information acquisition unit 48.

FIG. 7 is a view illustrating an example of the log information of the substrate processing apparatus. The log information of FIG. 7 represents the log information of the process including the plurality of steps performed by the substrate processing apparatus 10 subjected to the optimization of the process conditions. FIG. 7 represents an example where the log information is recorded for each of Steps 1 to 50, including the information of the process conditions such as step time, a heater temperature, and a gas flow rate.

For example, when the desired process step is the film formation step of the film Z, the process step identification unit 50 acquires the information of the gases A and B registered as process gases corresponding to the film formation step of the film Z, from the registration information of FIG. 6. The process step identification unit 50 identifies “Step 11” and “Step 12” during which the gases A and B flow, as process steps from the log information of FIG. 7. The process step identification unit 50 may identify “Step 11” and “Step 12” during which the gas A or B flows, as process steps from the log information of FIG. 7.

In this way, the process step identification unit 50 may identify the log information of the desired process step such as the film formation step or the etching step, from the log information of the substrate processing apparatus 10 subjected to the optimization, based on the acquired registration information.

In step S32, the process condition acquisition unit 52 of the optimization device 14 acquires the process conditions of the desired process step from the log information of the desired process step that has been identified in step S30. For example, in the example of FIGS. 6 and 7, the unoptimized process conditions of the process step are acquired from the log information of “Step 11” and “Step 12” during which the gases A and B flow.

In step S34, the optimization unit 54 of the optimization device 14 acquires the process result information corresponding to the log information of FIG. 7. In step S36, the optimization unit 54 performs the optimization calculation to optimize the process conditions of the desired process step, by using the process conditions of the desired process step that have been identified in step S32 and the process result information acquired in step S34. The optimization calculation may be performed using a known algorithm, and descriptions thereof are omitted.

Referring back to FIG. 4, the output unit 56 of the optimization device 14 performs the process of step S22. The output unit 56 outputs the process conditions of the desired process step that have been optimized by the optimization unit 54. The output unit 56 provides the optimized process conditions to the apparatus controller 12 to reflect the optimized process conditions in the process to be performed by the substrate processing apparatus 10.

The optimization device 14 repeats the process of steps S12 to S22, for example, until it is determined in step S16 that the process result satisfies the requirement. According to the present embodiment, the process conditions of the process step may be optimized such that the process result satisfies the requirement.

While the present embodiment describes an example where the process condition optimization calculation is performed online as illustrated in FIG. 1, the process condition optimization calculation may be performed offline. When the process condition optimization calculation is performed offline, for example, the exported log information and process result information may be input to the optimization device 14.

As illustrated in FIG. 6, the present embodiment describes an example where the name of the process gas used in the desired process step is registered as registration information. However, other than the process gas, the state of a knob used in the process step (ON/OFF of an RF power) may be registered.

The present embodiment describes an example where the process conditions of the process step are acquired from the log information. However, without being limited to the log information, the process conditions of the process step may be acquired from any information, which includes the process conditions of multiple steps from the start to the end of the process. For example, when actual measurement values are not required, the process conditions of the process step may be acquired from a process recipe, instead of the log information.

According to the present embodiment, even when there is no function to assign the process step to the substrate processing apparatus 10, the optimization device 14 may identify the process step using the registration information registered in the optimization device 14 by, for example, the operator. As a result, the optimization device 14 may acquire the process conditions of the process step from the log information of the identified process step, and optimize the process conditions.

Further, the present embodiment may be applied to the optimization of the process conditions of a process including a plurality of processes. For example, a process including the film formation and the etching, such as the depo edge depo (DED) may be considered.

By registering the process gas and the process type as registered information, the optimization device 14 may automatically acquire the film formation conditions and the etching conditions from the log information of the process step. According to the present embodiment, without requiring a specific operation for a plurality of interdependent processes, it is possible to optimize the film formation conditions and the etching conditions for forming or etching a desired film. Further, the present embodiment may be identically applied to a process such as Seed Poly including multiple different film formations. Further, the present embodiment may be applied to a process such as a process tube cleaning, which is not related to semiconductor wafers.

Further, in the present embodiment, since the process gas and the process type are registered as registration information, it is possible to optimize the process conditions of process steps that use the same process gas but belong to different process types.

According to the present disclosure, a technology may be provided to identify log information of a desired process step from log information of a substrate processing apparatus and perform a process condition optimization calculation.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
a registration reception circuitry configured to receive a registration of registration information for identifying log information of a desired process step from log information of a substrate processing apparatus that has performed a process including a plurality of steps according to a process condition;
an identification circuitry configured to identify the log information of the desired process step from the log information of the substrate processing apparatus, based on the registration information;
a process condition acquisition circuitry configured to acquire a process condition of the desired process step from the log information of the desired process step identified by the identification circuitry;
an optimization circuitry configured to optimize the process condition of the desired process step, using the process condition of the desired process step acquired by the process condition acquisition circuitry, and process result information of the process; and
an output circuitry configured to output the process condition of the desired process step optimized by the optimization circuitry.

2. The information processing apparatus according to claim 1, wherein the registration reception circuitry is configured to receive a registration of information of a process gas used in the desired process step, as the registration information for identifying the log information of the desired process step.

3. The information processing apparatus according to claim 1, wherein the registration reception circuitry is configured to receive a registration of information of a process gas used in the desired process step and information of a process type, as the registration information for identifying the log information of the desired process step.

4. The information processing apparatus according to claim 2, wherein the identification circuitry is configured to identify the log information of the desired process step that uses the process gas, from log information of the plurality of steps recorded in the log information of the substrate processing apparatus.

5. The information processing apparatus according to claim 4, wherein the desired process step is a film formation step or an etching step that uses the process gas.

6. A non-transitory computer-readable storage medium having stored therein a program that causes an information processing apparatus to execute a process including:
receiving a registration of registration information for identifying log information of a desired process step, from log information of a substrate processing apparatus that has performed a process including a plurality of steps according to a process condition;
based on the registration information, identifying the log information of the desired process step from the log information of the substrate processing apparatus;
acquiring a process condition of the desired process step from the log information of the desired process step identified in the identifying;
optimizing the process condition of the desired process step, using the process condition of the desired process step acquired in the acquiring, and process result information of the process; and
outputting the process condition of the desired process step optimized in the optimizing.

7. A process condition optimization method comprising:
providing a substrate processing system configured to optimize a process condition of at least one substrate processing apparatus that performs a process including a plurality of steps according to the process condition;
receiving a registration of registration information for identifying log information of a desired process step, from log information of the substrate processing apparatus;
based on the registration information, identifying the log information of the desired process step from the log information of the substrate processing apparatus;
acquiring a process condition of the desired process step from the log information of the desired process step identified in the identifying;
optimizing the process condition of the desired process step, using the process condition of the desired process step acquired in the acquiring, and process result information of the process; and
outputting the process condition of the desired process step optimized in the optimizing.
